(19) United States
(12) Patent Application Publication
(10) Pub. No.: US 2025/0318405 A1
(43) Pub. Date: Oct. 9, 2025

(54) DISPLAY PANEL, DISPLAY DEVICE AND METHOD OF MANUFACTURING DISPLAY PANEL

(71) Applicant: Hubei Yangtze industrial innovation Center of Advanced display Co., Ltd., Wuhan (CN)

(72) Inventor: Liang HU, Wuhan (CN)

(73) Assignee: Hubei Yangtze industrial innovation Center of Advanced display Co., Ltd., Wuhan (CN)

(21) Appl. No.: 18/744,736

(22) Filed: Jun. 17, 2024

(30) Foreign Application Priority Data
Apr. 8, 2024 (CN) 202410421322.7

(51) Int. Cl. H10K 59/80; H10K 59/12

(52) U.S. Cl. CPC H10K 59/873; H10K 59/1201; H10K 59/879

(57) ABSTRACT

A display panel, a display device and a method of manufacturing the display panel are provided by the present application. The display panel includes a display region, a separating region and an opening region. The separating region at least partially surrounds the opening region, and the display region at least partially surrounds the separating region. The display panel further includes a substrate, including a base; a separating structure, arranged on a side of the base, and located within the separating region; a first adhesive layer, arranged on a side of the separating structure away from the base, and at least partially covering the base and the separating structure; and a second adhesive layer, arranged on a side of the first adhesive layer away from the base. A thickness of a portion of the second adhesive layer within the display region is larger than that within the separating region.

### CROSS REFERENCES TO RELATED APPLICATIONS

This application claims a priority of Chinese Patent Application No. 202410421322.7, filed on Apr. 8, 2024 and titled by “DISPLAY PANEL, DISPLAY DEVICE AND METHOD OF MANUFACTURING DISPLAY PANEL”, which is incorporated herein in its entirety.

### TECHNICAL FIELD

The present application relates to the technical field of display, and in particular to a display panel, a display device and a method of manufacturing the display panel.

### BACKGROUND

In a display device, in order to achieve certain functions of the display device, it is necessary to provide a hole on a display panel, for example, to provide a camera function. A separating structure may be arranged around an opening position of the hole of the display panel, so as to prevent intrusion of water vapor or static electricity. At the separating structure, an optical adhesive with a high refractive index which is arranged on a light-emitting side of the display panel may generate the stress concentration, which may cause splitting and damage, thereby leading to the packaging failure of the optical adhesive with the high refractive index.

### SUMMARY

Embodiments of the present application provide a display panel, a display device and a method of manufacturing the display panel, which can reduce the risk of packaging failure.

In a first aspect, embodiments in the present application provide a display panel including a display region, a separating region and an opening region. The separating region at least partially surrounds the opening region, and the display region at least partially surrounds the separating region. The display panel further includes a substrate, including a base; a separating structure, arranged on a side of the base, and located within the separating region; a first adhesive layer, arranged on a side of the separating structure away from the base, and at least partially covering the base and the separating structure; and a second adhesive layer, arranged on a side of the first adhesive layer away from the base. A refractive index of the first adhesive layer is lower than a refractive index of the second adhesive layer. A thickness of a portion of the second adhesive layer within the display region is D1, a thickness of a portion of the second adhesive layer within the separating region is D2, and D1>D2≥0.

In a second aspect, embodiments in the present application provide a display device, including the display panel according to the embodiments in the first aspect.

In a third aspect, embodiments in the present application provide a method of manufacturing a display panel. The display panel includes a display region, a separating region and an opening region. The separating region at least partially surrounds the opening region, and the display region at least partially surrounds the separating region. The method of manufacturing the display panel includes: providing a substrate, which includes a base; manufacturing a separating structure on a side of the substrate within the separating region; applying a first adhesive layer on a side of the substrate to at least partially cover the base and the separating structure; applying a second adhesive layer on a side of the first adhesive layer away from the base, and curing the second adhesive layer through a first mask plate, in which a transmittance of a portion of the first mask plate within the display region is T1, a transmittance of a portion of the first mask plate within the separating region is T2, and T1>T2≥0, so that a thickness of a portion of the second adhesive layer within the display region is D1, a thickness of a portion of the second adhesive layer within the separating region is D2, and D1 is larger than D2; and cutting the opening region.

In the display panel, the display device and the method of manufacturing the display panel according to the embodiments of the present application, the separating region at least partially surrounds the opening region, the display region at least partially surrounds the separating region, and the separating structure is located within the separating region, so as to separate water vapor and static electricity. The first adhesive layer is arranged on the side of the separating structure away from the base, and the second adhesive layer is arranged on the side of the first adhesive layer away from the base. The refractive index of the first adhesive layer is lower than the refractive index of the second adhesive layer to package the display panel. The thickness of the portion of the second adhesive layer within the display region is D1, and the thickness of the portion of the second adhesive layer within the separating region is D2, and D1>D2≥0. By reducing the thickness of the portion of the second adhesive layer within the separating region, the stress concentration phenomenon of the second adhesive layer can be alleviated, the possibility of damage to the second adhesive layer can be reduced, and the risk of packaging failure can be reduced.

### BRIEF DESCRIPTION OF THE DRAWINGS

In order to more clearly illustrate the technical solution of the embodiments of the present application, the drawings required to be used in the embodiments of the present application will be briefly introduced below. It is apparent that the drawings described below merely show some embodiments of the present application. For those skilled in the art, other drawings can also be obtained according to these drawings without the inventive labor.

FIG. 1 shows a top view of a display panel according to an embodiment of the present application;

FIG. 2 shows a sectional view of the display panel in A-A section according to the embodiment of the present application in FIG. 1;

FIG. 3 shows another sectional view of the display panel in A-A section according to the embodiment of the present application in FIG. 1;

FIG. 4 shows another sectional view of the display panel in A-A section according to the embodiment of the present application in FIG. 1;

FIG. 5 shows another sectional view of the display panel in A-A section according to the embodiment of the present application in FIG. 1;

FIG. 6 shows another sectional view of the display panel in A-A section according to the embodiment of the present application in FIG. 1;

FIG. 7 shows another sectional view of the display panel in A-A section according to the embodiment of the present application in FIG. 1;

FIG. 8 shows another sectional view of the display panel in A-A section according to the embodiment of the present application in FIG. 1;

FIG. 9 shows another sectional view of the display panel in A-A section according to the embodiment of the present application in FIG. 1;

FIG. 10 shows another sectional view of the display panel in A-A section according to the embodiment of the present application in FIG. 1;

FIG. 11 shows another sectional view of the display panel in A-A section according to the embodiment of the present application in FIG. 1;

FIG. 12 shows a top view of a display device according to an embodiment of the present application;

FIG. 13 shows a flowchart of a method of manufacturing a display panel according to an embodiment of the present application; and

FIG. 14 shows another flowchart of a method of manufacturing a display panel according to an embodiment of the present application.

### REFERENCE NUMERALS

1. substrate; 11. base; 12. array layer; 121. thin film transistor; 13. Light-emitting device layer; 131. Light-emitting device;
2. separating structure; 21. first separating column; 22. second separating column;
3. first adhesive layer; 31. second groove; 32. fourth groove;
4. second adhesive layer; 41. first groove; 42. third groove; 43. cutting groove;
5. retaining wall structure;
100. display device; 200. display panel;
AA, display region; Q. separating region; Q1, first sub-region; Q2, second sub-region; B. retaining wall region; K. opening region.

### DETAILED DESCRIPTION

Features and exemplary embodiments in various aspects of the present application will be described in detail below. In the detailed description below, many specific details are presented to provide the comprehensive understanding of the present application. It is apparent to some skilled in the art that the present application can be practiced without some of these specific details. The description of the embodiments below is only to provide a better understanding of the present application by showing examples of the present application.

It should be noted that, in a case of no conflict, the embodiments of the present application and the features in the embodiments can be combined with one another. The embodiments will be described in detailed referring to the drawings below.

Relational terms such as first and second are merely used to distinguish one entity or operation from another entity or operation, and do not necessarily require or imply any such actual relationship or order between the entities or operations. Further, the term “comprise”, “include” or any other variations thereof is intended to encompass a non-exclusive inclusion, such that a process, method, article, or device including a plurality of elements includes not only these elements but also other elements not listed, or elements that are inherent to such process, method, article or device. Without more limitations, an element that is defined by an expression “comprises . . . ” does not exclude other identical elements in the process, method, article, or device comprising this element.

It should be understood that when the structure of a part is described, the expression of one layer or region being located “on” or “above” other layer or region may mean that one layer or region is directly located on other layer or region, or there is another layer or region between the one layer or region and the other layer or region. And if the part is flipped, the one layer or region is located “under” or “below” the other layer or region.

In addition, the term “and/or” in the present application is merely an association relationship describing associated objects, which means that there can be three types of relationships. For example, “A and/or B” may mean three cases that there is only A, there are both A and B, and there is only B. In addition, the punctuation mark “/” in the present application generally indicates that the related objects of the preceding content and following content are in an “or” relationship.

It should be understood that, in the embodiments of the present application, “B corresponding to A” indicates that B is associated with A, and B can be determined based on A. It should also be understood that B being determined based on A does not mean B being determined based on only A, but means B being determined based on A and/or other information.

The applicant found that a separating structure is arranged around an opening position of the display panel to form a separating region, so as to prevent the intrusion of water vapor and static electricity. The thickness of the display panel gradually decreases from a display region to an opening region. An optical adhesive with a high refractive index, which is used for packaging, covers both the display region and the separating region. When the optical adhesive with the high refractive index is manufactured, a liquid optical adhesive is applied on the display region and the separating region. Due to the thickness of the display panel gradually decreasing from the display region to the opening region and the influence of the gravity, a thickness of the optical adhesive with the high refractive index formed within the separating region is larger than that formed within the display region. After the opening position is cut, the optical adhesive with the high refractive index within the separating region may occurs the obvious stress concentration, crack, warping or other problems, which may affect the packaging effect of the display panel.

In view of the above analysis, embodiments of the present application provide a display panel, a display device and a method of manufacturing the display panel. The display panel includes a display region, a separating region and an opening region. The separating region at least partially surrounds the opening region, and the display region at least partially surrounds the separating region. The display panel further includes a substrate, a separating structure, a first adhesive layer and a second adhesive layer. A refractive index of the first adhesive layer is lower than a refractive index of the second adhesive layer. A thickness of a portion of the second adhesive layer within the display region is D1, a thickness of a portion of the second adhesive layer within the separating region is D2, and D1>D2≥0. By reducing the thickness of the portion of the second adhesive layer within the separating region, the stress concentration phenomenon of the second adhesive layer can be alleviated, the possibility of damage to the second adhesive layer can be reduced, and the risk of packaging failure can be reduced.

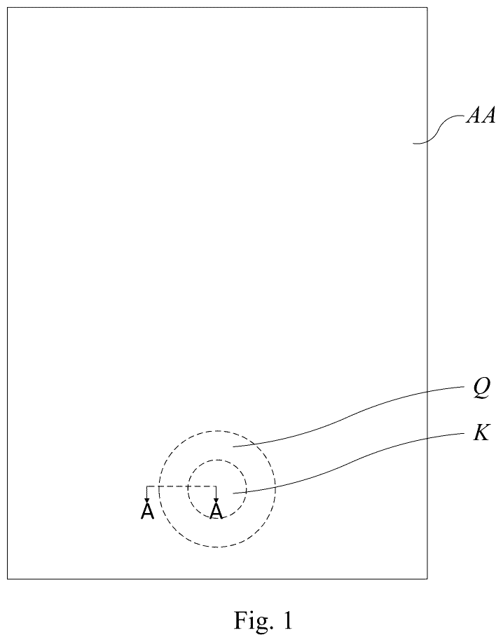

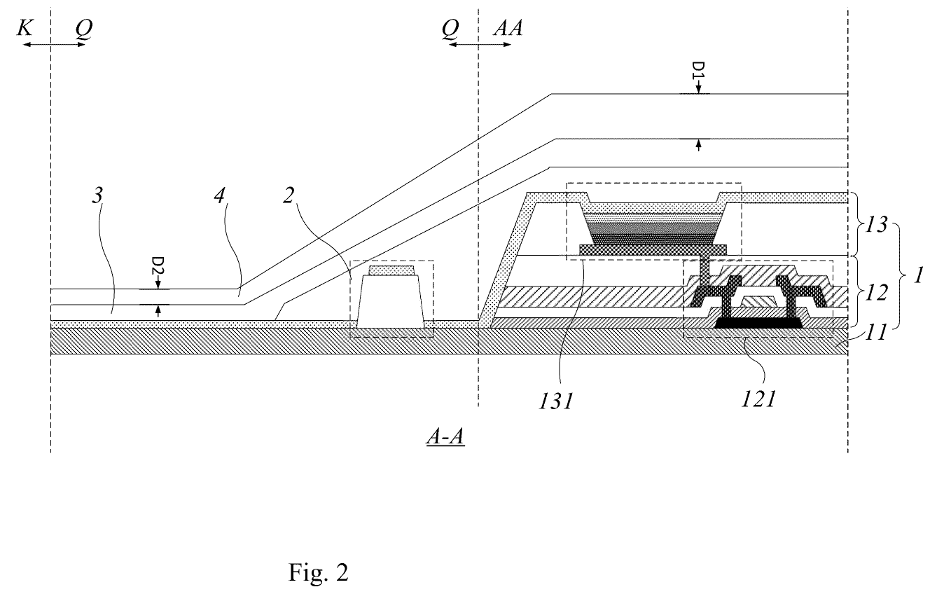

FIG. 1 shows a top view of a display panel according to an embodiment of the present application; FIG. 2 shows a sectional view of the display panel in A-A section according to the embodiment of the present application in FIG. 1.

Referring to FIG. 1 and FIG. 2, the embodiments in the present application provide a display panel including a display region AA, a separating region Q and an opening region K. The separating region Q at least partially surrounds the opening region K, and the display region AA at least partially surrounds the separating region Q. The display panel further includes a substrate 1, including a base 11; a separating structure 2, arranged on a side of the base 11, and located within the separating region Q; a first adhesive layer 3, arranged on a side of the separating structure 2 away from the base 11, and at least partially covering the base 11 and the separating structure 2; and a second adhesive layer 4, arranged on a side of the first adhesive layer 3 away from the base 11. A refractive index of the first adhesive layer 3 is lower than a refractive index of the second adhesive layer 4. A thickness of a portion of the second adhesive layer 4 within the display region AA is D1, a thickness of a portion of the second adhesive layer 4 within the separating region Q is D2, and D1>D2≥0.

In the embodiments of the present application, the display region AA of the display panel can display and emit the light, an opening of the display panel is located within the opening region K, the separating region Q at least partially surrounds the opening region K, the display region AA at least partially surrounds the separating region Q, and the separating region Q is arranged between the opening region K and the display region AA to prevent the water vapor from entering the display region AA through the opening of the opening region K.

The substrate 1 includes the base 11, which can be formed of the polymer materials such as glass, polyimide (PI), polycarbonate (PC), polyethersulfone (PES), polyethylene terephthalate (PET), polyethylene naphthalate (PEN), polyaryl compounds (PAR), or glass fiber reinforced plastics (FRP). The base 11 may be transparent, semi-transparent or opaque. In the embodiments of the present application, the base 11 may be a flexible substrate 1, and formed of the polymer, such as polyimide, with a relative thin thickness. In the display region AA, the substrate 1 may further include an array layer 12 and a light-emitting device layer 13. The array layer 12 includes a plurality of thin film transistors 121 (TFTs) and a pixel circuit formed of the thin film transistors 121, and is used to control a light-emitting device 131 of the light-emitting device layer 13 to display and emit the light.

The separating structure 2 is located within the separating region Q, so as to prevent the water vapor from entering the display region AA through the opening and reduce the impact of the water vapor on the display panel. The separating structure 2 is arranged on the side of the base 11 and protrudes in a direction away from the base 11.

The first adhesive layer 3 and the second adhesive layer 4 are both used to package the display panel to prevent the water vapor from entering the display region AA. The first adhesive layer 3 covers the substrate 1 and the separating structure 2, and the second layer covers the first adhesive layer 3. In addition, the refractive index of the first adhesive layer 3 is lower than the refractive index of the second adhesive layer 4, which can prevent the light of the display panel from emitting at a relatively large angle and improve the anti-peeping ability of the display panel. In a direction from the display region AA to the opening region K, in the separating region Q, a distance from a side of the second adhesive layer 4 facing the base 11 to the base 11 gradually decreases to form a slope shape. Therefore, after the second adhesive layer 4 is cured, the stress concentration may occur within the separating region Q in a process of cutting the opening within the opening region K. The thickness of the portion of the second adhesive layer 4 within the display region AA is D1, the thickness of the portion of the second adhesive layer 4 within the separating region Q is D2, and D1>D2≥0. That is, the thickness of the portion of the first adhesive layer 3 within the separating region Q is smaller than that within the display region AA. Since the thickness of the portion of the second adhesive layer 4 within the separating region Q is reduced, the stress generated by the second adhesive layer 4 during the process of cutting the opening can be reduced, thereby reducing the possibility of warping of the second adhesive layer 4 due to stress and the possibility of peeling or cracking of the separating structure 2, and reducing the risk of the packaging failure.

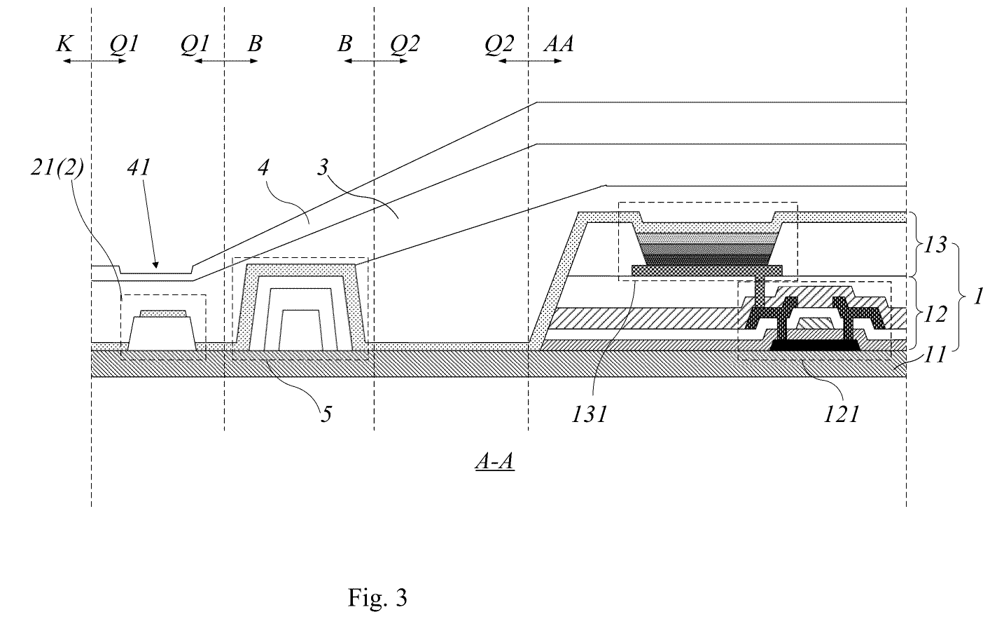

FIG. 3 shows another sectional view of the display panel in A-A section according to the embodiment of the present application in FIG. 1.

Further, referring to FIG. 3, the separating region Q includes a first sub-region Q1 and a second sub-region Q2, and the second sub-region Q2 at least partially surrounds the first sub-region Q1; the separating structure 2 includes a first separating column 21, which is located within the first sub-region Q1; and the second adhesive layer 4 includes a first groove 41, which overlaps with the first separating column 21 in a direction perpendicular to a plane where the base 11 is located.

The separating region Q includes the first sub-region Q1 and the second sub-region Q2. The second sub-region Q2 at least partially surrounds the first sub-region Q1, that is, the second sub-region Q2 surrounds the opening region K, the first sub-region Q1 surrounds the second sub-region Q2, and the display region AA surrounds the first sub-region Q1. The first separating column 21 of the separating structure 2 is located within the first sub-region Q1 to separate the water vapor. The first groove 41 is provided on the second adhesive layer 4. The first groove 41 overlaps with the first separating column 21 in the direction perpendicular to the plane where the base 11 is located. That is, the first groove 41 is provided on the side of the first separating column 21 away from the base 11. The first groove 41 can release a portion of the stress of the second adhesive layer 4 at the position of the first separating column 21, thereby reducing the force exerted by the second adhesive layer 4 on the first separating column 21 and reducing the risk of detachment and peeling of the first separating column 21.

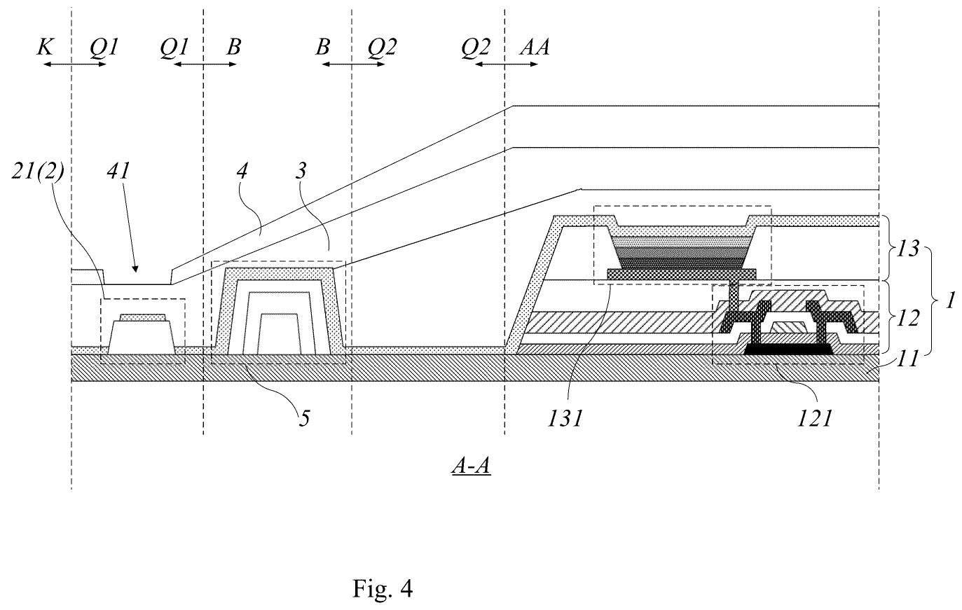

FIG. 4 shows another sectional view of the display panel in A-A section according to the embodiment of the present application in FIG. 1.

Further, referring to FIG. 4, the first groove 41 penetrates through the second adhesive layer 4. The second adhesive layer 4 can further move away from the first separating column 21. On the plane where base 11 is located, the second adhesive layer 4 is disconnected at the first separating column 21 to release the stress of the second adhesive layer 4, so that the force generated by the stress of the second adhesive layer 4 is difficult to directly act on the first separating column 21, thereby reducing the possibility of detachment and peeling of the first separating column 21 and reducing the risk of the packaging failure.

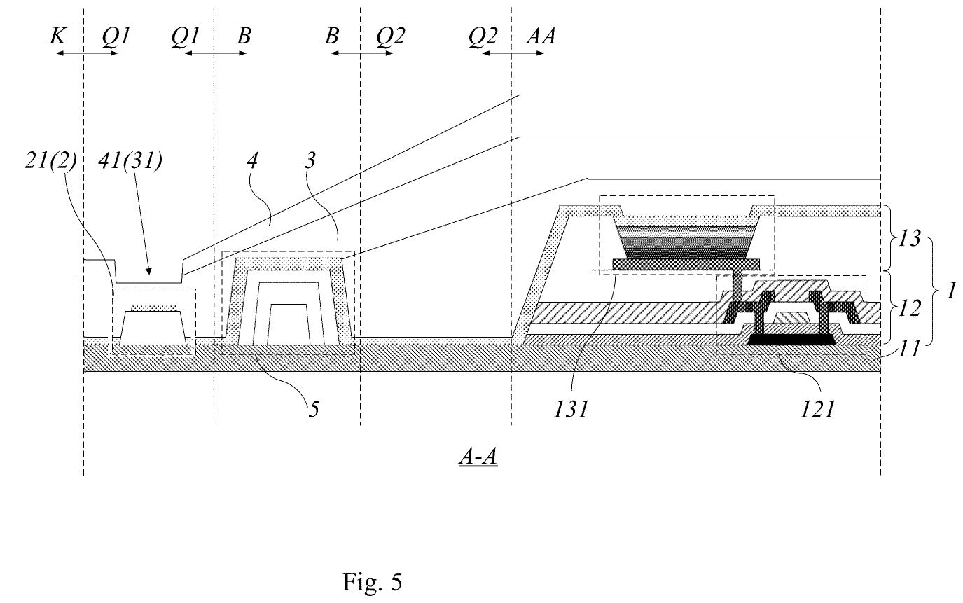

FIG. 5 shows another sectional view of the display panel in A-A section according to the embodiment of the present application in FIG. 1.

Further, referring to FIG. 5, the first adhesive layer 3 further includes a second groove 31, which is located on a side of the first adhesive layer 3 away from the base 11, and the second groove 31 overlaps with the first groove 41 in the direction perpendicular to the plane where the base 11 is located. Since the first groove 41 penetrates through the second adhesive layer 4, the first groove 41 and the second groove 31 can be formed as a whole. On the basis of reducing the stress of the second adhesive layer 4, it can also reduce the stress of the first adhesive layer 3, thereby reducing the risk of peeling off the first separating column 21. It should be noted that the second groove 31 should not penetrate the first adhesive layer 3. If the second groove 31 penetrates through the first adhesive layer 3, both the first adhesive layer 3 and the second adhesive layer 4 are in a disconnected state at the first separating column 21, which can reduce the structural strength of the display panel and affect the packaging of the first separating column 21.

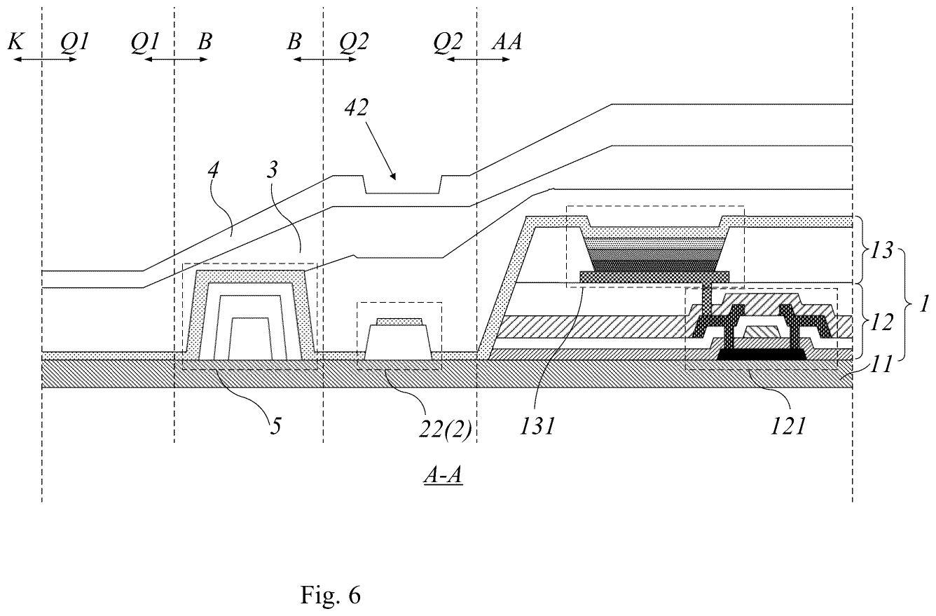

FIG. 6 shows another sectional view of the display panel in A-A section according to the embodiment of the present application in FIG. 1.

Optionally, referring to FIG. 6, the separating region Q includes a first sub-region Q1 and a second sub-region Q2, and the second sub-region Q2 at least partially surrounds the first sub-region Q1. The separating structure 2 includes a second separating column 22, which is located within the second sub-region Q2. The second adhesive layer 4 includes a third groove 42, which overlaps with the first separating column 21 in a direction perpendicular to a plane where the base 11 is located.

The separating region Q includes the first sub-region Q1 and the second sub-region Q2. The second sub-region Q2 at least partially surrounds the first sub-region Q1. That is, the second sub-region Q2 surrounds the opening region K, the first sub-region Q1 surrounds the second sub-region Q2, and the display region AA surrounds the first sub-region Q1. The second separating column 22 of the separating structure 2 is located within the first sub-region Q1 to separate the water vapor.

It should be noted that in a process of manufacturing the display panel, after cutting the opening region K, a distance from the first sub-region Q1 to the opening region K is smaller than a distance from the second sub-region Q2 to the opening region K. Therefore, the stress concentration phenomenon of the second adhesive layer 4 within the first sub-region Q1 is more pronounced than the stress concentration phenomenon of the second adhesive layer 4 within the second sub-region Q2. The possibility of detachment of the first separating column 21 due to the stress of the second adhesive layer 4 is higher than the possibility of detachment of the second separating column 22 due to the stress of the second adhesive layer 4. However, there is still a risk of detachment of the second separating column 22 due to the stress of the second adhesive layer 4.

A third groove 42 is provided on the second adhesive layer 4. The third groove 42 overlaps with the second separating column 22 in the direction perpendicular to the plane where the base 11 is located. That is, the third groove 42 is provided on a side of the second separating column 22 away from the base 11. The third groove 42 can release a portion of the stress of the second adhesive layer 4 at the position of the second separating column 22, thereby reducing the force exerted by the second adhesive layer 4 on the second separating column 22 and reducing the risk of detachment and peeling of the second separating column 22.

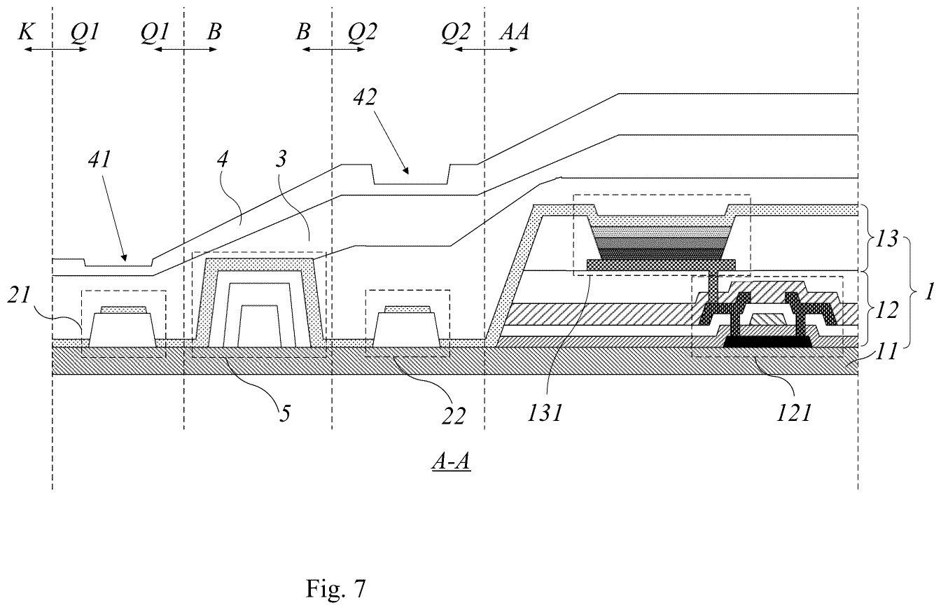

FIG. 7 shows another sectional view of the display panel in A-A section according to the embodiment of the present application in FIG. 1.

It should be noted that, as shown in FIG. 7, the separating structure 2 includes the first separating column 21 located within the first sub-region Q1. The second adhesive layer 4 is provided with the first groove 41, the separating structure 2 can also include a second separating structure 2 located within the second sub-region Q2, and the second adhesive layer 4 is provided with the third groove 42.

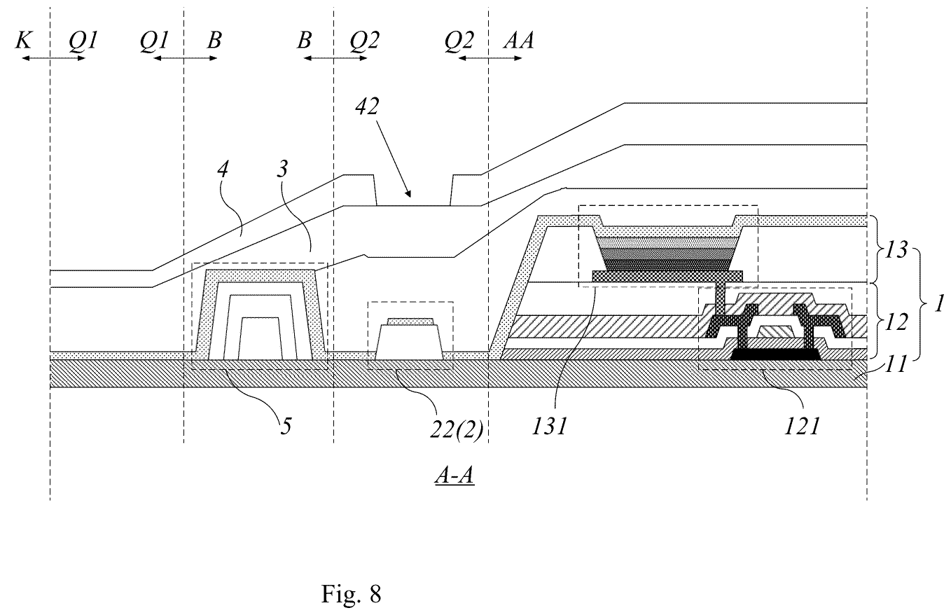

FIG. 8 shows another sectional view of the display panel in A-A section according to the embodiment of the present application in FIG. 1.

Further, referring to FIG. 8, the third groove 42 penetrates through the second adhesive layer 4, so that the second adhesive layer 4 can further move away from the second separating column 22. On the plane where the base 11 is located, the second adhesive layer 4 is disconnected at the second separating column 22 to release the stress of the second adhesive layer 4, so that the force generated by the stress of the second adhesive layer 4 is difficult to directly act on the second separating column 22, thereby reducing the possibility of detachment and peeling of the second separating column 22 and reducing the risk of the packaging failure.

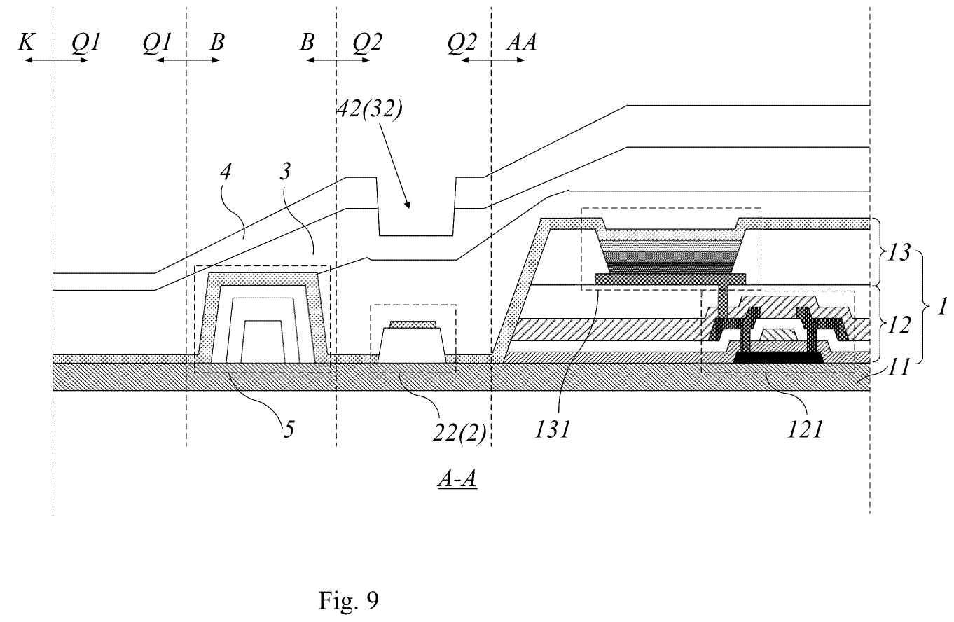

FIG. 9 shows another sectional view of the display panel in A-A section according to the embodiment of the present application in FIG. 1.

Further, referring to FIG. 9, the first adhesive layer 3 includes a fourth groove 32, which is located on the side of the first adhesive layer 3 away from the base 11, and overlaps with the third groove 42 in the direction perpendicular to the plane where the base 11 is located. Since the third groove 42 penetrates through the second adhesive layer 4, the third groove 42 and the fourth groove 32 can be formed as a whole. On the basis of reducing the stress of the second adhesive layer 4, it can also reduce the stress of the first adhesive layer 3, thereby reducing the risk of peeling off the second separating column 22. It should be noted that the fourth groove 32 should not penetrate the first adhesive layer 3, so as to reduce the impact on the structural strength of the display panel.

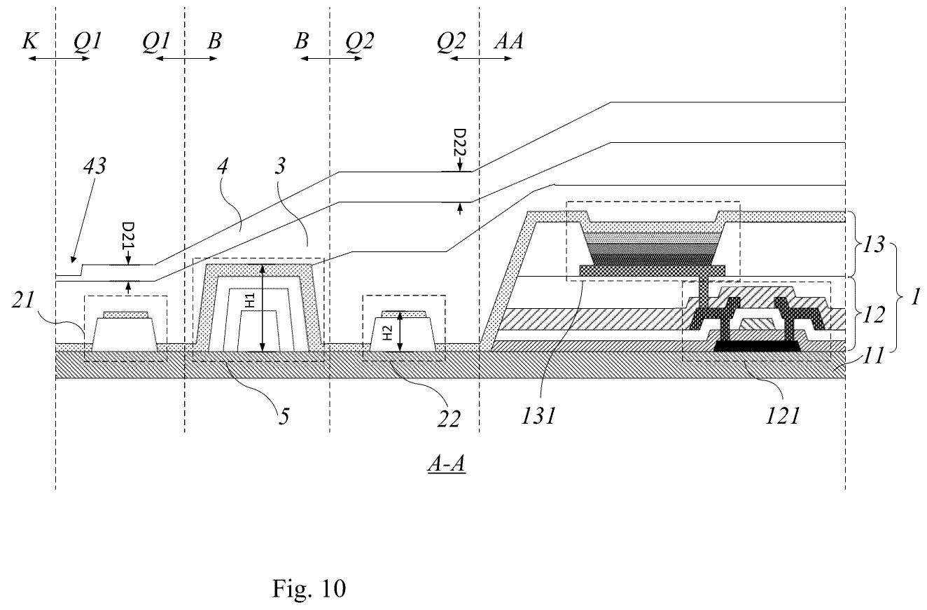

FIG. 10 shows another sectional view of the display panel in A-A section according to the embodiment of the present application in FIG. 1.

Further, referring to FIG. 10, the second adhesive layer 4 further includes a cutting groove, which is located at an edge of the separating region Q close to the opening region K.

An edge between the separating region Q and the opening region K is an edge of the opening of the display panel, which is a cutting line of the opening. The cutting groove 43 is located at the edge of the separating region Q close to the opening region K, that is, the cutting groove 43 extends to the cutting line in the direction from the display region AA to the opening region K. Therefore, when the opening is cut, the force generated at the cutting line may act less on the second adhesive layer 4, thereby reducing the stress generated by the second adhesive layer 4, reducing the possibility of detachment of the separating structure 2 due to the stress of the second adhesive layer 4, and reducing the risk of packaging failure of the display panel. When the cutting groove 43 is manufactured, in the direction from the display region AA to the opening region K, the groove is manufactured and extends to the opening region K, then the opening region K is cut. Thus, a remaining portion of the groove is the cutting groove 43.

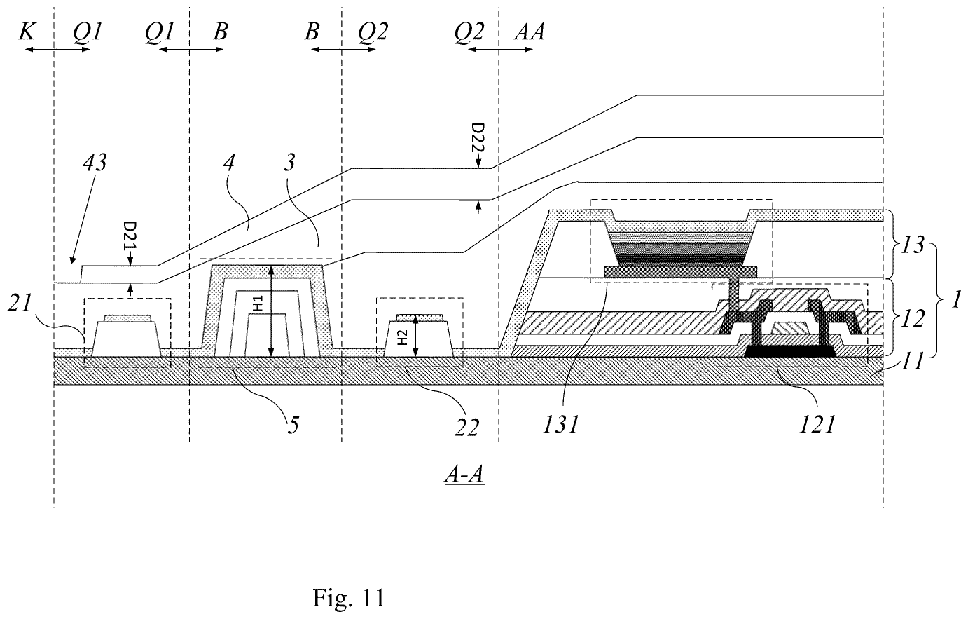

FIG. 11 shows another sectional view of the display panel in A-A section according to the embodiment of the present application in FIG. 1.

Further, referring to FIG. 11, the first adhesive layer 3 is exposed through the cutting groove. That is, the cutting groove 43 penetrates through the second adhesive layer 4. When the opening is cut, the force generated at the cutting line may not directly act on the second adhesive layer 4, thereby reducing the stress generated by the second adhesive layer 4, reducing the possibility of detachment of the separating structure 2 due to the stress of the second adhesive layer 4, and reducing the risk of packaging failure of the display panel.

Further, referring to FIG. 11, the separating region Q includes a first sub-region Q1, a retaining wall region B and a second sub-region Q2. The second sub-region Q2 at least partially surrounds the retaining wall region B, and the retaining wall region B at least partially surrounds the first sub-region Q1. The display panel further includes a retaining wall structure 5, which is located within the retaining wall region B, a distance from a side of the retaining wall structure 5 away from the base to the base 11 is H1, a distance from a side of the separating structure 2 away from the base 11 to the base is H2, and H1>H2. A thickness of a portion of the second adhesive layer 4 within the first sub-region Q1 is D21, a thickness of a portion of the second adhesive layer 4 within the second sub-region Q2 is D22, and D21≤D22.

The separating region Q includes the first sub-region Q1, the retaining wall region B and the second sub-region Q2. The second sub-region Q2 at least partially surrounds the retaining wall region B, and the retaining wall region B at least partially surrounds the first sub-region Q1. That is, the first sub-region Q1 surrounds the opening region K, the retaining wall region B surrounds the first sub-region Q1, the second sub-region Q2 surrounds the retaining wall region B, and the display region AA surrounds the second sub-region Q2. The retaining wall structure 5 is located within the retaining wall region B and is used to block the packaging material. In the process of manufacturing the display panel, when the display region AA is packaged, generally, the packaging material is the liquid material. The retaining wall structure 5 can block the packaging material to prevent it from flowing into the opening region K. The distance from the side of the retaining wall structure 5 away from the base 11 to the base 11 is H1, the distance from the side of the separating structure 2 away from the base 11 to the base 11 is H2, and H1>H2. That is, the retaining wall structure 5 is higher than the separating structure 2. When the separating structure 2 includes the second separating column 22 located within the second sub-region Q2, the packaging material blocked by the retaining wall structure 5 may cover the second separating column 22. The thickness D21 of a portion of the second adhesive layer 4 within the first sub-region Q1 is smaller than or equal to the thickness D22 of a portion of the second adhesive layer 4 within the second sub-region Q2. Since a distance between the first sub-region Q1 and the opening region K is smaller than a distance between the second sub-region Q2 and the opening region K, the portion of the second adhesive layer 4 within the first sub-region Q1 is more prone to the stress concentration, so that the thickness of the portion of the second adhesive layer 4 within the first sub-region Q1 is smaller. Thus, on the basis of reducing the thickness of the portion of the second adhesive layer 4 within the whole separating region Q, the thickness of the portion of the second adhesive layer 4 within the first sub-region Q1 can be further reduced, thereby further reducing the possibility of detachment and peeling of the separating structure 2 due to the stress of the second adhesive layer 4, and reducing the risk of packaging failure of the display panel.

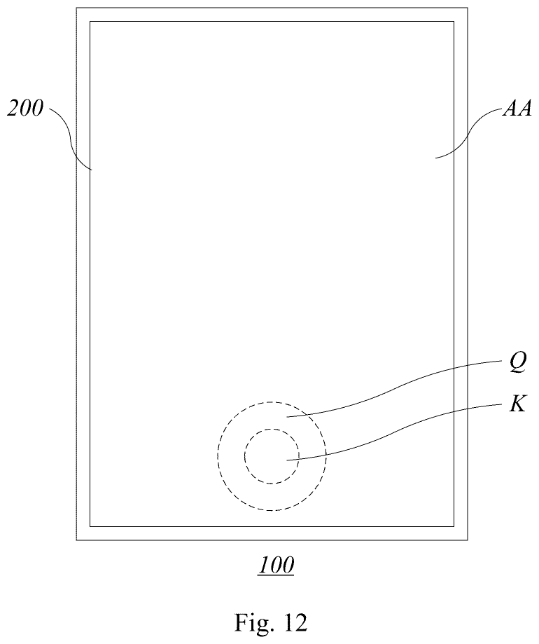

FIG. 12 shows a top view of a display device according to an embodiment of the present application.

Referring to FIG. 12, embodiments of the present application further provide a display device 100 including the display panel 200 according to the embodiments as described above. The display device 100 provided by embodiments of the present application may be a product or part having the display function, such as a mobile phone, a tablet, a television, a monitor, a laptop, a digital photo frame or a navigation device.

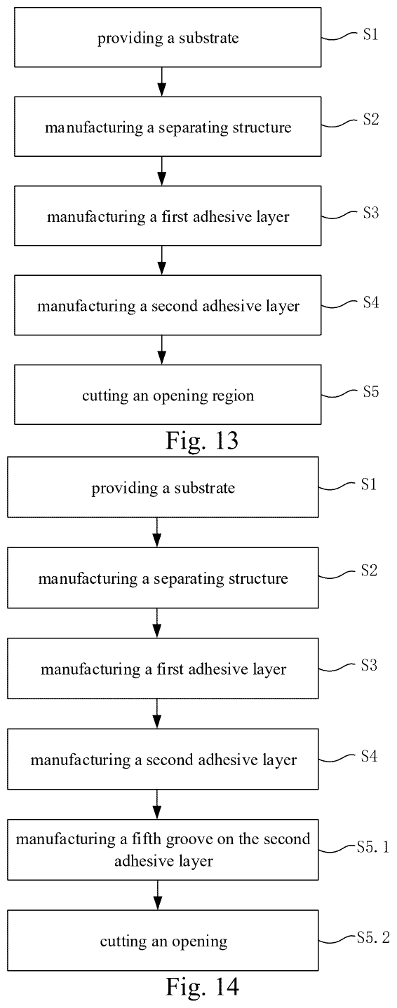

FIG. 13 shows a flowchart of a method of manufacturing a display panel according to an embodiment of the present application.

Referring to FIG. 13, the embodiments of the present application further provide a method of manufacturing a display panel 200, which can be applied to manufacture the display panel 200 in the embodiments of the present application as described above. The display panel 200 includes the display region AA, the separating region Q and the opening region K, the separating region Q at least partially surrounds the opening region K, and the display region AA at least partially surrounds the separating region Q. The display region AA of the display panel 200 can display and emit light, and the opening region K of the display panel 200 is provided with an opening.

Referring to FIG. 13, the method of manufacturing the display panel 200 in the embodiments of present application includes:

Step S1: providing a substrate 1.

The substrate 1 can be directly obtained or manufactured. The substrate 1 includes a base 11, and further includes an array layer 12 and a light-emitting device layer 13. The array layer 12 includes a plurality of thin film transistors 121 to form a pixel circuit, which can control a light-emitting device 131 of the light-emitting device layer 13 to display and emit the light. It should be noted that at this time, the opening within the opening region K of display panel 200 has not been cut yet, and the packaging of the display panel 200 has not been completed yet.

Step S2: manufacturing a separating structure 2.

In the separating region Q, the separating structure 2 is manufactured on a side of the base 11, and the separating structure 2 and the array layer 12 are located on the same side of the base 11. The separating structure 2 can separate the water vapor from entering the display region AA from the opening region K.

Step S3: manufacturing a first adhesive layer 3.

The first adhesive layer 3 is applied on a side of substrate 1 to at least partially cover the base 11 and separating structure 2. When the first adhesive layer 3 is applied, the material of the first adhesive layer 3 has a certain fluidity and forms the first adhesive layer 3 after being cured.

Step S4: manufacturing a second adhesive layer 4.

The second adhesive layer 4 is applied on a side of the first adhesive layer 3 away from the base 11, and is cured through a first mask plate. The material of the second adhesive layer 4 has a certain fluidity when the second adhesive layer 4 is applied. The material of the first adhesive layer 3 is cured through illumination. In a process of the illumination, the light intensity at different positions of the second adhesive layer 4 can be adjust through the first mask plate. The larger the transmittance of the first mask plate is, the larger the light intensity received by the second adhesive layer 4 is, and the thicker the thickness of the second adhesive layer 4 is. In the display region AA, the transmittance of the first mask plate is T1; in the separating region Q, the transmittance of the first mask plate is T2; and T1>T2≥0. Therefore, the thickness of a portion of the second adhesive layer 4 within the display region AA is D1, the thickness of a portion of the second adhesive layer 4 within the separating region Q is D2, and D1 is larger than D2.

Step S5: cutting the opening region K.

The opening of the display panel 200 is formed by cutting in the opening region K. In a process of cutting, the stress on the second adhesive layer 4 can be generated. As the thickness D1 of the portion of the second adhesive layer 4 within the display region AA is larger than the thickness D2 of the portion of the second adhesive layer 4 within the separating region Q, the stress generated by the second adhesive layer 4 can be reduced, thereby reducing the possibility of detachment of the separating structure 2 from the base 11 due to the stress of the second adhesive layer 4, and reducing the risk of packaging failure of the display panel 200.

Further, in step S4, 20%·T1>T2. That is, the transmittance T2 of a portion of the first mask plate within the separating region Q is less than 20% of the transmittance T1 of a portion of the first mask plate within the display region AA, so that the thickness D1 of the portion of the second adhesive layer 4 within the display region AA is larger than the thickness D2 of the portion of the second adhesive layer 4 within the separating region Q.

Further, the separating region Q includes a first sub-region Q1 and a second sub-region Q2, and the second sub-region Q2 at least partially surrounds the first sub-region Q1. The separating structure 2 includes a first separating column 21, which is located within the first sub-region Q1. In step S4 of applying a second adhesive layer 4 on the side of the first adhesive layer 3 away from the base 11, and curing the second adhesive layer 4 through the first mask plate further includes: removing a portion of the second adhesive layer 4 to form a first groove 41, in which the first groove 41 overlaps with the first separating column 21 in a direction perpendicular to a plane where the base 11 is located.

After the second adhesive layer 4 is manufactured, the first groove 41 can be manufactured by means of etching. The first groove 41 may not penetrate through the second adhesive layer 4 or may penetrate the second adhesive layer 4. The first groove 41 overlaps with the first separating column 21 in the direction perpendicular to the plane where the base 11 is located, which can reduce the stress of the second adhesive layer 4 acting on the first separating column 21, reduce the possibility of detachment of the first separating column 21, and reduce the risk of packaging failure.

Further, the separating region Q includes the first sub-region Q1 and the second sub-region Q2, the second sub-region Q2 at least partially surrounds the first sub-region Q1, the separating structure 2 includes the second separating column 22, which is located within the second sub-region Q2. In step S4 of applying a second adhesive layer 4 on the side of the first adhesive layer 3 away from the base 11, and curing the second adhesive layer 4 through the first mask plate further includes: removing a portion of the second adhesive layer 4 to form a second groove 31, in which the second groove 31 overlaps with the second separating column 22 in the direction perpendicular to the plane where the base 11 is located.

After the second adhesive layer 4 is manufactured, the second groove 31 can be manufactured by means of etching. The second groove 31 may not penetrate through the second adhesive layer 4 or may penetrate the second adhesive layer 4. The second groove 31 overlaps with the second separating column 22 in the direction perpendicular to the plane where the base 11 is located, which can reduce the stress of the second adhesive layer 4 acting on the second separating column 22, reduce the possibility of detachment of the second separating column 22, and reduce the risk of packaging failure.

FIG. 14 shows another flowchart of a method of manufacturing a display panel according to an embodiment of the present application.

Further, referring to FIG. 14, step S5 of the cutting the opening region K includes step S5.1: manufacturing a fifth groove on the second adhesive layer 4;

The fifth groove is formed by removing a portion of the second adhesive layer 4. One portion of the fifth groove is located within the separating region Q, and the other portion of the fifth groove is located within the opening region K. That is, the fifth groove needs to cross a boundary line between the separating region Q and the opening region K.

step S5.2: cutting an opening.

The opening region K and a portion of the fifth groove located within the opening region K are removed by cutting along the boundary line between the separating region Q and the opening region K. In the separating region Q, a cutting groove is formed of a remaining portion of the fifth groove, so as to reduce the stress generated by the second adhesive layer 4 during cutting.

In summary, the embodiments in the present application provide the display panel including the display region, the separating region and the opening region. In the display panel, the separating region at least partially surrounds the opening region, the display region at least partially surrounds the separating region, and the separating structure is located within the separating region, so as to separate water vapor and static electricity. The first adhesive layer is arranged on the side of the separating structure away from the base, and the second adhesive layer is arranged on the side of the first adhesive layer away from the base. The refractive index of the first adhesive layer is lower than the refractive index of the second adhesive layer to package the display panel. The thickness of the portion of the second adhesive layer within the display region is D1, and the thickness of the portion of the second adhesive layer within the separating region is D2, and D1>D2≥0. By reducing the thickness of the portion of the second adhesive layer within the separating region, the stress concentration phenomenon of the second adhesive layer can be alleviated, the possibility of damage to the second adhesive layer can be reduced, and the risk of packaging failure can be reduced.

The above description is only the specific embodiments of the present application, and the scope of the present application is not limited to this. Any skilled in the art familiar with the technical field within the scope of the disclosed technology can easily think of various equivalent modifications or replacements, which should be included in the scope of the present application. Therefore, the scope of the present application shall be based on the scope of the claims.

What is claimed is:

1. A display panel, characterized by comprising a display region, a separating region and an opening region, the separating region at least partially surrounding the opening region, the display region at least partially surrounding the separating region, and the display panel further comprising:
a substrate, comprising a base;
a separating structure, arranged on a side of the base, and located within the separating region;
a first adhesive layer, arranged on a side of the separating structure away from the base, and at least partially covering the base and the separating structure; and
a second adhesive layer, arranged on a side of the first adhesive layer away from the base, and a refractive index of the first adhesive layer being lower than a refractive index of the second adhesive layer; a thickness of a portion of the second adhesive layer within the display region being D1, a thickness of a portion of the second adhesive layer within the separating region being D2, and D1>D2≥0.

2. The display panel according to claim 1, characterized in that the separating region comprises a first sub-region and a second sub-region, and the second sub-region at least partially surrounds the first sub-region;
the separating structure comprises a first separating column, which is located within the first sub-region; and
the second adhesive layer comprises a first groove, which overlaps with the first separating column in a direction perpendicular to a plane where the base is located.

3. The display panel according to claim 2, characterized in that the first groove penetrates through the second adhesive layer.

4. The display panel according to claim 2, characterized in that the first adhesive layer further comprises a second groove, which is located on the side of the first adhesive layer away from the base, and the second groove overlaps with the first groove in the direction perpendicular to the plane where the base is located.

5. The display panel according to claim 1, characterized in that the separating region comprises a first sub-region and a second sub-region, and the second sub-region at least partially surrounds the first sub-region;
the separating structure comprises a second separating column, which is located within the second sub-region; and
the second adhesive layer comprises a third groove, which overlaps with the second separating column in a direction perpendicular to a plane where the base is located.

6. The display panel according to claim 5, characterized in that the third groove penetrates through the second adhesive layer.

7. The display panel according to claim 5, characterized in that the first adhesive layer comprises a fourth groove, which is located on the side of the first adhesive layer away from the base, and overlaps with the third groove in the direction perpendicular to the plane where the base is located.

8. The display panel according to claim 1, characterized in that the second adhesive layer further comprises a cutting groove, which is located at an edge of the separating region close to the opening region.

9. The display panel according to claim 8, characterized in that the first adhesive layer is exposed through the cutting groove.

10. The display panel according to claim 1, characterized in that the separating region comprises a first sub-region, a retaining wall region and a second sub-region, the second sub-region at least partially surrounds the retaining wall region, and the retaining wall region at least partially surrounds the first sub-region;
the display panel further comprises a retaining wall structure, which is located within the retaining wall region, a distance from a side of the retaining wall structure away from the base to the base is H1, a distance from a side of the separating structure away from the base to the base is H2, and H1>H2; and
a thickness of a portion of the second adhesive layer within the first sub-region is D21, a thickness of a portion of the second adhesive layer within the second sub-region is D22, and D21≤D22.

11. A display device, characterized by comprising the display panel according to claim 1.

12. A method of manufacturing a display panel, characterized in that the display panel comprises a display region, a separating region and an opening region, the separating region at least partially surrounds the opening region, and the display region at least partially surrounds the separating region;
the method of manufacturing the display panel comprises:
providing a substrate, which comprises a base;
manufacturing a separating structure on a side of the substrate within the separating region;
applying a first adhesive layer on the side of the substrate to at least partially cover the base and the separating structure;
applying a second adhesive layer on a side of the first adhesive layer away from the base, and curing the second adhesive layer through a first mask plate; wherein a transmittance of a portion of the first mask plate within the display region is T1, a transmittance of a portion of the first mask plate within the separating region is T2, and T1>T2≥0, so that a thickness of a portion the second adhesive layer within the display region is D1, a thickness of a portion of the second adhesive layer within the separating region is D2, and D1 is larger than D2; and
cutting the opening region.

13. The method of manufacturing the display panel according to claim 12, characterized in that 20%·T1>T2.

14. The method of manufacturing the display panel according to claim 12, characterized in that the separating region comprises a first sub-region and a second sub-region, the second sub-region at least partially surrounds the first sub-region, the separating structure comprises a first separating column, and the first separating column is located within the first sub-region;
and before the cutting the opening region, the method of manufacturing the display panel further comprises:
removing a portion of the second adhesive layer to form a first groove, which overlaps with the first separating column in a direction perpendicular to a plane where the base is located.

15. The method of manufacturing the display panel according to claim 12, characterized in that the separating region comprises a first sub-region and a second sub-region, the second sub-region at least partially surrounds the first sub-region, and the separating structure comprises a second separating column, which is located in the second sub-region; and
the applying the second adhesive layer on the side of the first adhesive layer away from the base, and curing the second adhesive layer through the first mask plate further comprises:
removing a portion of the second adhesive layer to form a second groove, which overlaps with the second separating column in a direction perpendicular to a plane where the base is located.

16. The method of manufacturing the display panel according to claim 12, characterized in that the cutting the opening region comprises:
removing a portion of the second adhesive layer to form a fifth groove, wherein a portion of the fifth groove is located within the separating region and the other portion of the fifth groove is located within the opening region; and
removing the opening region and the portion of the fifth groove located within the opening region, and forming a cutting groove by the portion of the fifth groove located within the separating region.
